(19) United States
(12) Patent Application Publication
(10) Pub. No.: US 2025/0157960 A1
(43) Pub. Date: May 15, 2025

(54) SEMICONDUCTOR PACKAGE

(71) Applicant: SAMSUNG ELECTRONICS CO., LTD., Suwon-si (KR)

(72) Inventors: Sangho CHA, Suwon-si (KR); Yun-Rae Cho, Suwon-si (KR)

(73) Assignee: SAMSUNG ELECTRONICS CO., LTD., Suwon-si (KR)

(21) Appl. No.: 18/937,941

(22) Filed: Nov. 5, 2024

(30) Foreign Application Priority Data
Nov. 13, 2023 (KR) 10-2023-0156492

(51) Int. Cl. H01L 23/00; H01L 23/31; H01L 25/065

(52) U.S. Cl. CPC H01L 24/05; H01L 24/06; H01L 24/16; H01L 25/0657; H01L 23/3107; H01L 2224/0401; H01L 2224/05552; H01L 2224/05557; H01L 2224/05563; H01L 2224/06051; H01L 2224/06179; H01L 2224/16146; H01L 2225/06513; H01L 2225/06517; H01L 2225/06541; H01L 2225/06565

(57) ABSTRACT

A semiconductor package includes: a first semiconductor chip having a first region and a second region contacting the first region; and a second semiconductor chip on a top surface of the first semiconductor chip, wherein the first semiconductor chip includes: a first pad in the first region and on the top surface of the first semiconductor chip, the first pad comprising a first pad portion and a first protrusion protruding from a top surface of the first pad portion; and a second pad in the second region and on the top surface of the first semiconductor chip and having a flat top surface.

### CROSS-REFERENCE TO RELATED APPLICATIONS

This application is based on and claims priority under 35 U.S.C. § 119 to Korean Patent Application No. 10-2023-0156492, filed on Nov. 13, 2023, in the Korean Intellectual Property Office, the disclosure of which is incorporated by reference herein in its entirety.

### BACKGROUND

The present disclosure relates to a semiconductor package and a method of manufacturing the same, and more particularly, to a semiconductor package including a bump structure and a method of manufacturing the same.

High-performance, high-speed and small electronic components have been increasingly demanded with the development of an electronic industry. To satisfy these demands, a packaging technique of providing a plurality of semiconductor chips in a single package has been suggested.

Recently, portable devices have been increasingly demanded in the electronics market, and thus small and light electronic components mounted in the electronics have been required. A semiconductor package technique of integrating a plurality of individual components in a single package as well as a technique of reducing a size of an individual component may be required to realize small and light electronic components.

### SUMMARY

Provided are a semiconductor package with improved structural stability and a method of manufacturing the same.

According to an aspect of the disclosure, a semiconductor package includes: a first semiconductor chip having a first region and a second region contacting with the first region; a second semiconductor chip on a top surface of the first semiconductor chip; a first connection terminal; and a second connection terminal, wherein the first semiconductor chip includes: a first pad in the first region and on the top surface of the first semiconductor chip, the first pad comprising a first pad portion and a first protrusion protruding from a top surface of the first pad portion; and a second pad in the second region and on the top surface of the first semiconductor chip and having a flat top surface, the second semiconductor chip includes: a third pad in the first region and on a bottom surface of the second semiconductor chip; and a fourth pad in the second region and on the bottom surface of the second semiconductor chip, the first pad and the third pad are connected to each other through the first connection terminal, and the second pad and the fourth pad are connected to each other through the second connection terminal.

According to an aspect of the disclosure, a semiconductor package may include a substrate having a first region and a second region, a base chip disposed on the substrate, second semiconductor chips stacked on a top surface of the base chip, a substrate connection terminal disposed on a bottom surface of the substrate, and a molding layer surrounding the base chip and the second semiconductor chips on the substrate. The substrate may include a first pad disposed on a top surface of the substrate of the first region, a protrusion disposed on a top surface of the first pad, and a second pad disposed on the top surface of the substrate of the second region. A width of the protrusion may be less than a width of the first pad. The base chip may be electrically connected to the substrate through a connection terminal provided on a bottom surface of the base chip. A separation distance between the top surface of the substrate and the bottom surface of the base chip on the first region may be greater than a separation distance between the top surface of the substrate and the bottom surface of the base chip on the second region.

According to an aspect of the disclosure, a semiconductor package includes: a first semiconductor chip having a central region and a peripheral region surrounding the central region in a plan view; and a second semiconductor chip on a top surface of the first semiconductor chip, wherein the first semiconductor chip includes a first pad and a second pad which are disposed on the top surface of the first semiconductor chip, wherein the first pad may include at least one protrusion on a top surface of the first pad, a height of the first pad is greater than a height of the second pad, one of the first pad and the second pad is in the central region on the top surface of the first semiconductor chip, and the other one of the first pad and the second pad is in the peripheral region and on the top surface of the first semiconductor chip.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view illustrating a semiconductor package according to one or more embodiments of the disclosure;

FIG. 2 is an enlarged view of a region ‘A’ of FIG. 1 to illustrate a semiconductor chip and a connection terminal according to one or more embodiments of the disclosure;

FIG. 3 is a cross-sectional view illustrating a shape of a semiconductor chip pad according to one or more embodiments of the disclosure;

FIG. 4 is a plan view illustrating a shape of a semiconductor chip pad according to one or more embodiments of the disclosure;

FIG. 5 is a cross-sectional view illustrating a state in which warpage occurs at a semiconductor package according to one or more embodiments of the disclosure;

FIG. 6 is a plan view illustrating arrangement of a first region of a semiconductor chip according to one or more embodiments of the disclosure;

FIGS. 7 and 8 are cross-sectional views illustrating states in which warpage occurs at semiconductor packages according to one or more embodiments of the disclosure;

FIG. 9 is cross-sectional view illustrating a semiconductor package according to one or more embodiments of the disclosure;

FIG. 10 is cross-sectional view illustrating a semiconductor package according to one or more embodiments of the disclosure; and

FIGS. 11 to 13 are cross-sectional views illustrating a method of manufacturing a semiconductor package according to one or more embodiments of the disclosure.

### DETAILED DESCRIPTION

The description merely illustrates the principles of the disclosure. Those skilled in the art will be able to devise one or more arrangements that, although not explicitly described herein, embody the principles of the disclosure. Furthermore, all examples recited herein are principally intended expressly to be only for explanatory purposes to help the reader in understanding the principles of the disclosure and the concepts contributed by the inventor to furthering the art and are to be construed as being without limitation to such specifically recited examples and conditions. Moreover, all statements herein reciting principles, aspects, and embodiments of the disclosure, as well as specific examples thereof, are intended to encompass equivalents thereof.

Terms used in the disclosure are used only to describe a specific embodiment, and may not be intended to limit the scope of another embodiment. A singular expression may include a plural expression unless it is clearly meant differently in the context. The terms used herein, including a technical or scientific term, may have the same meaning as generally understood by a person having ordinary knowledge in the technical field described in the present disclosure. Terms defined in a general dictionary among the terms used in the present disclosure may be interpreted with the same or similar meaning as a contextual meaning of related technology, and unless clearly defined in the present disclosure, it is not interpreted in an ideal or excessively formal meaning. In some cases, even terms defined in the disclosure cannot be interpreted to exclude embodiments of the present disclosure.

In one or more embodiments of the disclosure described below, a hardware approach is described as an example. However, since the one or more embodiments of the disclosure include technology that uses both hardware and software, the various embodiments of the present disclosure do not exclude a software-based approach.

In addition, in the disclosure, in order to determine whether a specific condition is satisfied or fulfilled, an expression of more than or less than may be used, but this is only a description for expressing an example, and does not exclude description of more than or equal to or less than or equal to. A condition described as ‘more than or equal to’ may be replaced with ‘more than’, a condition described as ‘less than or equal to’ may be replaced with ‘less than’, and a condition described as ‘more than or equal to and less than’ may be replaced with ‘more than and less than or equal to’.

The terms “include” and “comprise”, and the derivatives thereof refer to inclusion without limitation. The term “or” is an inclusive term meaning “and/or”. The phrase “at least one of,” when used with a list of items, means that different combinations of one or more of the listed items may be used, and only one item in the list may be needed. For example, “at least one of A, B, and C” includes any of the following combinations: A, B, C, A and B, A and C, B and C, and A and B and C, and any variations thereof. As an additional example, the expression “at least one of a, b, or c” may indicate only a, only b, only c, both a and b, both a and c, both b and c, all of a, b, and c, or variations thereof. Similarly, the term “set” means one or more. Accordingly, the set of items may be a single item or a collection of two or more items.

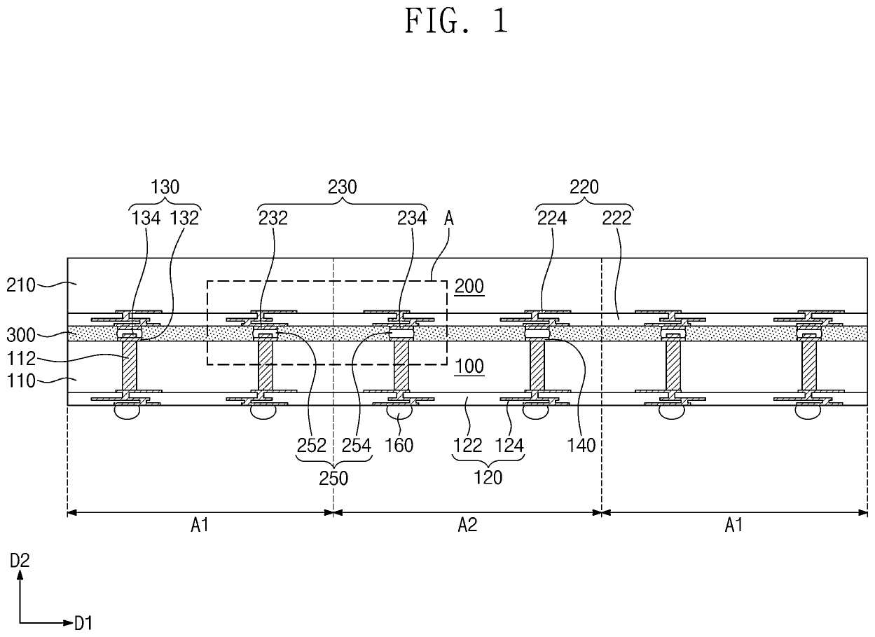

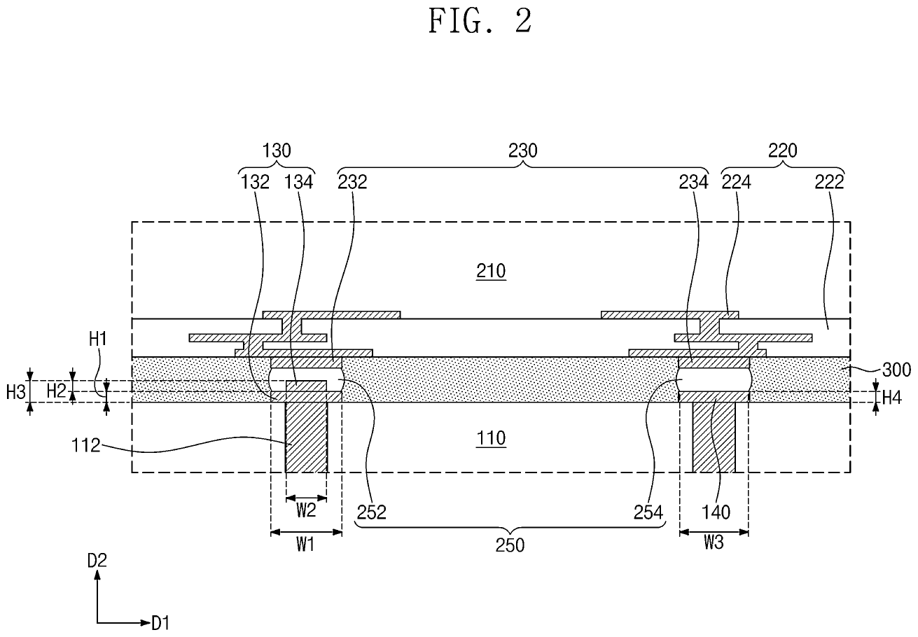

Semiconductor packages according to the disclosure will be described hereinafter with reference to the accompanying drawings. FIG. 1 is a cross-sectional view illustrating a semiconductor package according to one or more embodiments of the disclosure. FIG. 2 is an enlarged view of a region ‘A’ of FIG. 1 to illustrate a semiconductor chip and a connection terminal according to one or more embodiments of the disclosure.

Referring to FIGS. 1 and 2, a first semiconductor chip 100 may be provided. The first semiconductor chip 100 may include a first region A1 and a second region A2. The first region A1 of the first semiconductor chip 100 may be a region in which first pads 130 to be described below are provided. The second region A2 of the first semiconductor chip 100 may be a region in which second pads 140 to be described below are provided and may be a remaining region of the first semiconductor chip 100 except the first region A1. The first region A1 and the second region A2 may be in contact with each other. In other words, the first region A1 and the second region A2 may have an interface therebetween and may touch each other. The first region A1 may correspond to an outer portion of the first semiconductor chip 100. The second region A2 may correspond to a central portion of the first semiconductor chip 100. The first region A1 may surround the second region A2 when viewed in a plan view. The first region A1 may have a closed shape extending along an edge of the first semiconductor chip 100. A bottom surface of the first semiconductor chip 100 may be an active surface. The first semiconductor chip 100 may include a first base layer 110 and a first interconnection layer 120.

The first base layer 110 may include a semiconductor substrate. For example, the first base layer 110 may be a semiconductor substrate such as a semiconductor wafer. The first base layer 110 may be a silicon (Si) substrate, a silicon-on-insulator (SOI) substrate, a germanium (Ge) substrate, a germanium-on-insulator (GOI) substrate, a silicon-germanium (SiGe) substrate, a group III-V semiconductor substrate, or a substrate having an epitaxial thin layer obtained by performing a selective epitaxial growth (SEG) process. For example, the first base layer 110 may include at least one of silicon (Si), germanium (Ge), silicon-germanium (SiGe), gallium arsenic (GaAs), indium gallium arsenic (InGaAs), aluminum gallium arsenic (AlGaAs), or any mixture thereof. In one or more embodiments, an integrated circuit may be provided on a bottom surface of the first base layer 110. The integrated circuit may include a logic circuit or a memory circuit. In other words, the first semiconductor chip 100 may be a logic chip or a memory chip. However, embodiments of the disclosure are not limited thereto, and in certain embodiments, the first semiconductor chip 100 may include the logic chip, the memory chip, a semiconductor chip including at least one of other various integrated devices, or a passive device.

The first interconnection layer 120 may be disposed on the bottom surface of the first base layer 110. For example, the first interconnection layer 120 may include a first insulating pattern 122 and a first interconnection pattern 124, which are formed on the bottom surface of the first base layer 110. The first interconnection layer 120 may further include a circuit pattern or a protective layer as needed.

The first insulating pattern 122 may cover the integrated circuit on the bottom surface of the first base layer 110. The first insulating pattern 122 may include an insulating material. For example, the first insulating pattern 122 may include silicon oxide (SiO), silicon nitride (SiN), silicon oxynitride (SiON), silicon carbonitride (SiCN), or an insulating polymer. Alternatively, the first insulating pattern 122 may include an insulating polymer or a photoimageable dielectric (PID) material. For example, the photoimageable dielectric material may include at least one of photosensitive polyimide, polybenzoxazole, a phenol-based polymer, or a benzocyclobutene-based polymer.

The first interconnection pattern 124 may be provided in the first insulating pattern 122. The first interconnection pattern 124 may be electrically connected to the integrated circuit formed on the bottom surface of the first base layer 110. The first interconnection pattern 124 may include a conductive material. For example, the first interconnection pattern 124 may include copper (Cu) or aluminum (Al).

The first semiconductor chip 100 may include first lower pads provided on the bottom surface of the first semiconductor chip 100. The first lower pads may be disposed on the bottom surface of the first semiconductor chip 100 (i.e., a bottom surface of the first interconnection layer 120.) In other words, the first lower pads may be exposed on the bottom surface of the first semiconductor chip 100. Here, the first lower pads may be portions of the first interconnection pattern 124 which are exposed on a bottom surface of the first insulating pattern 122 of the first interconnection layer 120 or may be additional pads disposed on the bottom surface of the first insulating pattern 122 of the first interconnection layer 120 so as to be connected to the first interconnection pattern 124. The first lower pads may be electrically connected to the integrated circuit, formed on the bottom surface of the first base layer 110, through the first interconnection pattern 124 in the first interconnection layer 120.

External terminals 160 may be provided on the bottom surface of the first semiconductor chip 100. The external terminals 160 may be provided on bottom surfaces of the first lower pads. Each of the external terminals 160 may include a solder ball or a solder bump. The external terminals 160 may be electrically connected to the integrated circuit in the first semiconductor chip 100 through the first lower pads.

First through-electrodes 112 may be provided in the first semiconductor chip 100. The first through-electrodes 112 may be spaced apart from each other. At least one or more first through-electrodes 112 may be provided in each of the first region A1 and the second region A2. The first through-electrodes 112 may vertically penetrate the first base layer 110. One end of each of the first through-electrodes 112 may be connected to the first interconnection layer 120. The one end of each of the first through-electrodes 112 may be electrically connected to the first interconnection pattern 124 of the first interconnection layer 120 or the integrated circuit formed on the bottom surface of the first base layer 110. Another end of each of the first through-electrodes 112 may be exposed at a top surface of the first base layer 110.

In the first region A1, the first pads 130 may be provided on a top surface of the first semiconductor chip 100. The first pads 130 may be disposed on the outer portion of the first semiconductor chip 100. The first pads 130 may be arranged to surround the second region A2 when viewed in a plan view and may be spaced apart from each other. The first pads 130 may be disposed on the top surface of the first base layer 110. The first pads 130 may protrude from the top surface of the first semiconductor chip 100. Each of the first pads 130 may be connected to a top surface of each of the first through-electrodes 112 disposed in the first semiconductor chip 100 in the first region A1. The top surfaces of the first through-electrodes 112 disposed in the first region A1 may be in contact with central portions of bottom surfaces of the first pads 130, respectively. The first pads 130 may be electrically connected to the integrated circuit of the first semiconductor chip 100 through the first through-electrodes 112. Each of the first pads 130 may include a first pad portion 132 and a first protrusion 134 protruding from a top surface of the first pad portion 132.

Each of the first pad portions 132 may have a circular shape or a polygonal shape when viewed in a plan view. For example, a planar shape of each of the first pad portions 132 may be an octagonal shape. However, embodiments of the disclosure are not limited thereto, and in certain embodiments, the planar shape of each of the first pad portions 132 may be variously changed as needed. A first height H1 of each of the first pad portions 132 in a second direction D2 may range from about 1 μm to about 5 μm. A first width W1 of each of the first pad portions 132 in a first direction D1 may be substantially equal to or greater than a width, in the first direction D1, of the first through-electrode 112 corresponding to each of the first pad portions 132. The first pad portions 132 may include a conductive material. For example, the conductive material may include a metal such as nickel (Ni), copper (Cu), gold (Au), aluminum (Al) and/or tungsten (W). In the disclosure, the first direction D1 may be defined as a direction parallel to the top surface of the first semiconductor chip 100, and the second direction D2 may be defined as a direction perpendicular to the top surface of the first semiconductor chip 100.

Each of the first protrusions 134 may protrude from the top surface of a corresponding one of the first pad portions 132 in the second direction D2. A bottom surface of the first protrusion 134 may be in contact with the top surface of the first pad portion 132. The bottom surface of the first protrusion 134 may be located on a central portion of the top surface of the first pad portion 132. In other words, the first protrusion 134 may be spaced apart from side surfaces of the first pad portion 132. The whole of the first protrusion 134 may vertically overlap with the first pad portion 132 corresponding to the first protrusion 134 when viewed in a plan view. The first protrusions 134 may be electrically connected to the first through-electrodes 112 through the first pad portions 132.

Each of the first protrusions 134 may have a circular shape or a polygonal shape when viewed in a plan view. For example, a planar shape of each of the first protrusions 134 may be an octagonal shape. The planar shape of the first protrusion 134 may be substantially the same as the planar shape of the first pad portion 132. However, embodiments of the disclosure are not limited thereto. A second width W2 of each of the first protrusions 134 in the first direction D1 may be less than the first width W1 of each of the first pad portions 132. The second width W2 of the first protrusion 134 may range from about 70% to about 90% of the first width W1 of the first pad portion 132. A second height H2 of each of the first protrusions 134 in the second direction D2 may range from about 1 μm to about 5 μm. The first protrusions 134 may include a conductive material. For example, the conductive material may include a metal such as nickel (Ni), copper (Cu), gold (Au), aluminum (Al) and/or tungsten (W). The first protrusion 134 and the first pad portion 132 may be formed of different materials.

The first protrusion 134 and the first pad portion 132 are formed of different materials and an interface exists between the first protrusion 134 and the first pad portion 132 in FIG. 1, but embodiments of the disclosure are not limited thereto. In certain embodiments, the material of the first protrusions 134 may be the same as the material of the first pad portions 132. The first protrusion 134 and the first pad portion 132 which are connected to each other may be formed in a single body. In other words, the first protrusion 134 and the first pad portion 132 may constitute a continuous component, and the interface between the first pad portion 132 and the first protrusion 134 may not be visible.

In addition, the first protrusion 134 has a uniform width as a level in the second direction D2 increases in FIG. 1, but embodiments of the disclosure are not limited thereto. In certain embodiments, the width of the first protrusion 134 may become progressively less from the bottom surface of the first protrusion 134 toward a top surface of the first protrusion 134. A cross section of the first protrusion 134 may have a triangular shape or a trapezoid shape. In this case, the second width W2 of the first protrusion 134 may mean a width in the first direction D1, which is measured at a contact area of the first protrusion 134 and the first pad portion 132.

In the second region A2, the second pads 140 may be disposed on the top surface of the first semiconductor chip 100. The second pads 140 may be disposed on the central portion of the first semiconductor chip 100 and may be spaced apart from each other. For example, the second pads 140 may be horizontally spaced apart from the first pads 130. The first pads 130 may be arranged to surround the second pads 140 when viewed in a plan view, and the second pads 140 may be located between the first pads 130. The second pads 140 may be disposed on the top surface of the first base layer 110. The second pads 140 may protrude from the top surface of the first semiconductor chip 100. In the second region A2, each of the second pads 140 may be connected to the top surface of a corresponding one of the first through-electrodes 112 disposed in the first semiconductor chip 100. In the second region A2, the top surfaces of the first through-electrodes 112 may be in contact with central portions of bottom surfaces of the second pads 140. The second pads 140 may be electrically connected to the integrated circuit of the first semiconductor chip 100 through the first through-electrodes 112.

Each of the second pads 140 may have a circular shape or a polygonal shape when viewed in a plan view. For example, a planar shape of each of the second pads 140 may be an octagonal shape. The planar shape of each of the second pads 140 may be the same as the planar shape of each of the first pad portions 132. However, embodiments of the disclosure are not limited thereto, and in certain embodiments, the planar shape of each of the second pads 140 may be variously changed as needed. Each of the second pads 140 may have a flat top surface. In other words, a height from the bottom surface of the second pad 140 to the top surface of the second pad 140 may be uniform. A fourth height H4 of each of the second pads 140 in the second direction D2 may range from about 1 μm to about 5 μm. The fourth height H4 of the second pad 140 may be equal to the first height H1 of the first pad portion 132. A third width W3 of each of the second pads 140 in the first direction D1 may be equal to or less than the first width W1 of each of the first pad portions 132. A third height H3 from the bottom surface of the first pad portion 132 to the top surface of the first protrusion 134 may range from about 150% to about 250% of the fourth height H4 of the second pad 140. The second height H2 of the first protrusion 134 may range from about 50% to about 150% of the fourth height H4 of the second pad 140. The second pads 140 may include a conductive material. For example, the conductive material may include a metal such as nickel (Ni), copper (Cu), gold (Au), aluminum (Al) and/or tungsten (W). The material of the second pads 140 may be the same as the material of the first pad portions 132.

A second semiconductor chip 200 may be provided on the top surface of the first semiconductor chip 100. A bottom surface of the second semiconductor chip 200 may be an active surface. The second semiconductor chip 200 may include a second base layer 210 and a second interconnection layer 220.

The second base layer 210 may include a semiconductor substrate. For example, the second base layer 210 may be a semiconductor substrate such as a semiconductor wafer. The second base layer 210 may be a silicon (Si) substrate, a silicon-on-insulator (SOI) substrate, a germanium (Ge) substrate, a germanium-on-insulator (GOI) substrate, a silicon-germanium (SiGe) substrate, a group III-V semiconductor substrate, or a substrate having an epitaxial thin layer obtained by performing a selective epitaxial growth (SEG) process. For example, the second base layer 210 may include at least one of silicon (Si), germanium (Ge), silicon-germanium (SiGe), gallium arsenic (GaAs), indium gallium arsenic (InGaAs), aluminum gallium arsenic (AlGaAs), or any mixture thereof. In an embodiment, an integrated circuit may be provided on a bottom surface of the second base layer 210. The integrated circuit may include a logic circuit or a memory circuit. In other words, the second semiconductor chip 200 may be a logic chip or a memory chip. However, embodiments of the disclosure are not limited thereto, and in certain embodiments, the second semiconductor chip 200 may include the logic chip, the memory chip, a semiconductor chip including at least one of other various integrated devices, or a passive device.

The second interconnection layer 220 may be disposed on the bottom surface of the second base layer 210. For example, the second interconnection layer 220 may include a second insulating pattern 222 and a second interconnection pattern 224, which are formed on the bottom surface of the second base layer 210. The second interconnection layer 220 may further include a circuit pattern or a protective layer as needed.

The second insulating pattern 222 may cover the integrated circuit on the bottom surface of the second base layer 210. The second insulating pattern 222 may include an insulating material. For example, the second insulating pattern 222 may include silicon oxide (SiO), silicon nitride (SiN), silicon oxynitride (SiON), silicon carbonitride (SiCN), or an insulating polymer. Alternatively, the second insulating pattern 222 may include an insulating polymer or a photoimageable dielectric material (PID). For example, the photoimageable dielectric material may include at least one of photosensitive polyimide, polybenzoxazole, a phenol-based polymer, or a benzocyclobutene-based polymer.

The second interconnection pattern 224 may be provided in the second insulating pattern 222. The second interconnection pattern 224 may be electrically connected to the integrated circuit formed on the bottom surface of the second base layer 210. The second interconnection pattern 224 may include a conductive material. For example, the second interconnection pattern 224 may include copper (Cu) or aluminum (Al).

The second semiconductor chip 200 may include second lower pads 230 provided on the bottom surface of the second semiconductor chip 200. The second lower pads 230 may be disposed on the bottom surface of the second semiconductor chip 200 (i.e., a bottom surface of the second interconnection layer 220). The second lower pads 230 may protrude from the bottom surface of the second semiconductor chip 200. Here, the second lower pads 230 may be portions of the second interconnection pattern 224 which are exposed on a bottom surface of the second insulating pattern 222 of the second interconnection layer 220 or may be additional pads disposed on the bottom surface of the second insulating pattern 222 so as to be connected to the second interconnection pattern 224. The second lower pads 230 may be electrically connected to the integrated circuit, formed on the bottom surface of the second base layer 210, through the second interconnection pattern 224 in the second interconnection layer 220.

The second lower pads 230 may include third pads 232 disposed on top surfaces of the first pads 130 on the first region A1, and fourth pads 234 disposed on the top surfaces of the second pads 140 on the second region A2.

The third pads 232 may be spaced apart from each other on the bottom surface of the second semiconductor chip 200. The third pads 232 may be arranged to surround the second region A2 when viewed in a plan view and may be spaced apart from each other. Each of the third pads 232 may face a corresponding one of the first pads 130. A bottom surface of the third pad 232 may face the top surface of the first pad 130. A width of the third pad 232 in the first direction D1 may be equal to the first width W1 of the first pad portion 132. However, embodiments of the disclosure are not limited thereto. The width of the third pad 232 in the first direction D1 may be equal to or greater than the second width W2 of the first protrusion 134. At least a portion of the third pad 232 may vertically overlap with the first pad portion 132 corresponding to the third pad 232 when viewed in a plan view. The third pad 232 may vertically overlap with the whole of the first protrusion 134.

The fourth pads 234 may be spaced apart from each other on the bottom surface of the second semiconductor chip 200. The fourth pads 234 may be spaced apart from each other in the second region A2 when viewed in a plan view. Each of the fourth pads 234 may face a corresponding one of the second pads 140. A bottom surface of the fourth pad 234 may face the top surface of the second pad 140. A width of the fourth pad 234 in the first direction D1 may be equal to the third width W3 of the second pad 140. However, embodiments of the disclosure are not limited thereto. At least a portion of the fourth pad 234 may vertically overlap with the second pad 140 corresponding to the fourth pad 234 when viewed in a plan view.

Connection terminals 250 may be provided on the bottom surface of the second semiconductor chip 200. The connection terminals 250 may be provided on bottom surfaces of the second lower pads 230. The connection terminals 250 may be provided between the first semiconductor chip 100 and the second semiconductor chip 200. The connection terminals 250 may electrically connect the second semiconductor chip 200 to the first semiconductor chip 100. Each of the connection terminals 250 may include a solder ball or a solder bump. The connection terminals 250 may include first connection terminals 252 disposed on the bottom surfaces of the third pads 232 on the first region A1, and second connection terminals 254 disposed on the bottom surfaces of the fourth pads 234 on the second region A2.

On the first region A1, each of the first connection terminals 252 may be disposed between a corresponding one of the first pads 130 and a corresponding one of the third pads 232, which face each other. One end of each of the first connection terminals 252 may be in contact with the bottom surface of the corresponding third pad 232. Another end of each of the first connection terminals 252 may be in contact with the top surface of the first pad portion 132 facing the corresponding third pad 232.

The first connection terminals 252 may surround the top surfaces and side surfaces of the first protrusions 134. The first protrusions 134 may be inserted in the first connection terminals 252. Bottom surfaces of the first connection terminals 252 may be in contact with the top surfaces of the first pad portions 132. The top surfaces and the side surfaces of the first protrusions 134 may be located in the first connection terminals 252.

The first connection terminals 252 completely surround the side surfaces of the first protrusions 134 and the bottom surfaces of the first connection terminals 252 are in contact with the top surfaces of the first pad portions 132 in FIG. 1, but embodiments of the disclosure are not limited thereto. In certain embodiments, the first connection terminal 252 may surround at least a portion of the side surface of the first protrusion 134. Thus, a lower portion of the side surface of the first protrusion 134 may be exposed. For example, at least a portion of the first protrusion 134 may be inserted in the first connection terminal 252. The top surface of the first protrusion 134 may be located in the first connection terminal 252. The bottom surface of the first connection terminal 252 may be spaced apart from the top surface of the first pad portion 132.

A width of the first connection terminal 252 in the first direction D1 may be greater than the width of the third pad 232 in the first direction D1. The first connection terminal 252 may laterally protrude from a side surface of the third pad 232. However, embodiments of the disclosure are not limited thereto. The width of the first connection terminal 252 in the first direction D1 may be equal to or less than the width of the third pad 232 in the first direction D1.

On the second region A2, each of the second connection terminals 254 may be disposed between a corresponding one of the second pads 140 and a corresponding one of the fourth pads 234, which face each other. One end of the second connection terminal 254 may be in contact with the bottom surface of the corresponding fourth pad 234. Another end of the second connection terminal 254 may be in contact with the top surface of the second pad 140 facing the corresponding fourth pad 234.

A width of the second connection terminal 254 in the first direction D1 may be greater than the width of the fourth pad 234 in the first direction D1. The second connection terminal 254 may laterally protrude from a side surface of the fourth pad 234. However, embodiments of the disclosure are not limited thereto. The width of the second connection terminal 254 in the first direction D1 may be equal to or less than the width of the fourth pad 234 in the first direction D1. The width of the second connection terminal 254 in the first direction D1 may be equal to or less than the width of the first connection terminal 252 in the first direction D1.

An adhesive layer 300 may be provided between the first semiconductor chip 100 and the second semiconductor chip 200. In an embodiment, the adhesive layer 300 may laterally protrude from a side surface of the first semiconductor chip 100. The adhesive layer 300 may include a non-conductive film (NCF). The adhesive layer 300 may surround the first and second pads 130 and 140, the second lower pads 230 and the connection terminals 250 between the first semiconductor chip 100 and the second semiconductor chip 200. The adhesive layer 300 may prevent occurrence of electrical short between the connection terminals 250.

In the following embodiments, the same components as mentioned in the embodiments of FIGS. 1 and 2 will be indicated by the same reference numerals or the same reference designators, and the descriptions to them will be omitted or mentioned briefly for the purpose of ease and convenience in explanation. In other words, differences between the embodiments of FIGS. 1 and 2 and the following embodiments will be mainly described hereinafter.

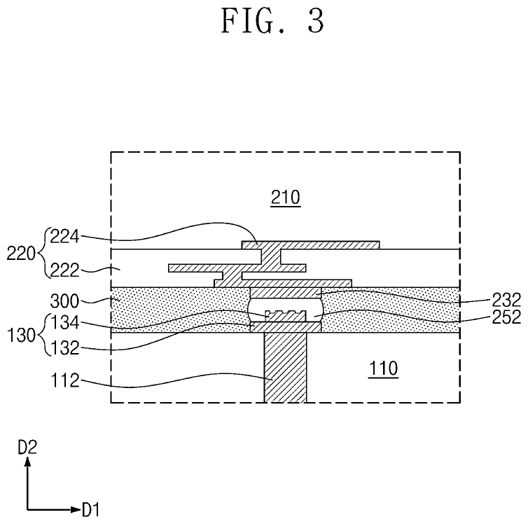

FIG. 3 is a cross-sectional view illustrating a shape of a first pad of a semiconductor package according to one or more embodiments of the disclosure.

The first protrusions 134 have the flat top surfaces in FIG. 1, but embodiments of the disclosure are not limited thereto. Referring to FIG. 3, the top surface of the first protrusion 134 may not be flat. A height from the bottom surface of the first protrusion 134 to the top surface of the first protrusion 134 may not be uniform. The first protrusion 134 may include at least one concave portion formed in the top surface of the first protrusion 134. The concave portion may have a shape recessed from the top surface of the first protrusion 134 into the first protrusion 134. The concave portion may not completely penetrate the first protrusion 134. In other words, a depth of the concave portion in the second direction D2 may be less than the second height H2 of the first protrusion 134. A level of a bottom surface of the concave portion may be higher than a level of the bottom surface of the first protrusion 134. The concave portion may be provided in plurality. The plurality of concave portions may be spaced apart from each other in the top surface of each of the first protrusions 134. Since the concave portion is provided in the top surface of the first protrusion 134, a surface area of the top surface of the first protrusion 134 may be increased. Thus, a contact area between each of the first protrusions 134 and a corresponding one of the first connection terminals 252 may be increased. Since the contact area between the first connection terminal 252 and the first protrusion 134 is increased, the first pad 130 may be stably connected to the first connection terminal 252, and the semiconductor package with improved electrical stability may be provided.

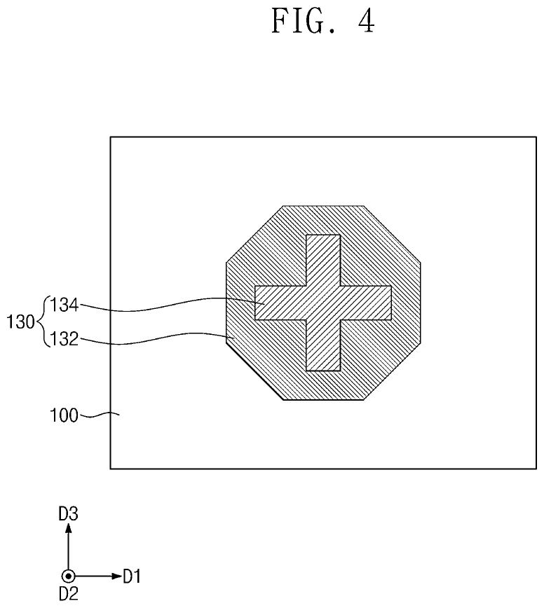

FIG. 4 is a plan view illustrating a shape of a first pad of a semiconductor package according to one or more embodiments of the disclosure.

The planar shape of the first protrusion 134 is the circular shape or the polygonal shape in FIG. 1, but embodiments of the disclosure are not limited thereto. Referring to FIG. 4, the planar shape of the first protrusion 134 may be a cross shape. In other words, each of the first protrusions 134 may have extending portions extending from a center of the first protrusion 134 in the first direction D1 and an opposite direction to the first direction D1, and extending portions extending from the center of the first protrusion 134 in a third direction D3 and an opposite direction to the third direction D3. In the disclosure, the third direction D3 may be defined as a direction intersecting the first direction D1 and the second direction D2. Angles, each of which is defined between side surfaces of the extending portions adjacent to each other, may be equal to each other. For example, the angle between the side surfaces of the adjacent extending portions may be 90 degrees. However, embodiments of the disclosure are not limited thereto. The number of the extending portions and the angle between the side surfaces of the extending portions may be variously changed. Since the planar shape of the first protrusion 134 is the cross shape, a surface area of the first protrusion 134 (i.e., a sum of areas of the top surface and the side surface of the first protrusion 134) may be increased. Thus, a contact area between each of the first protrusions 134 and a corresponding one of the first connection terminals 252 may be increased. Since the contact area between the first connection terminal 252 and the first protrusion 134 is increased, the first pad 130 may be stably connected to the first connection terminal 252, and the semiconductor package with improved electrical stability may be provided.

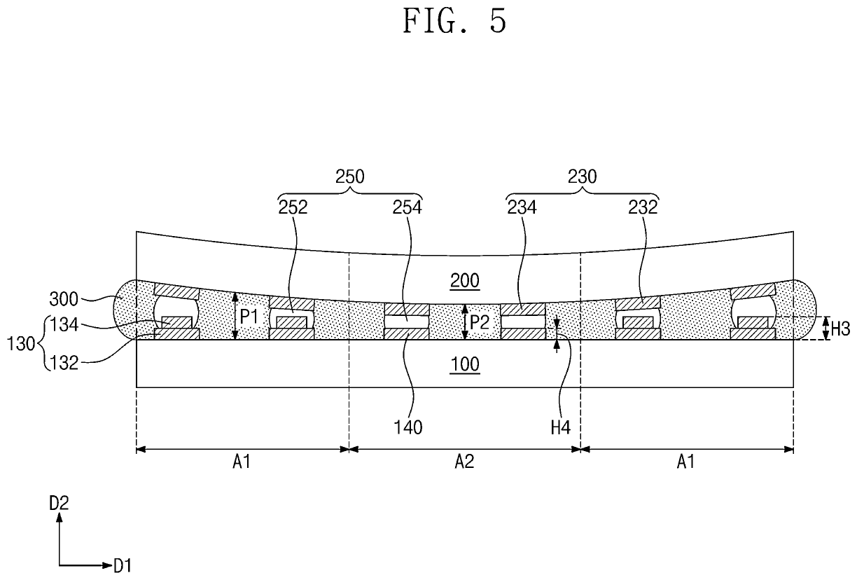

FIG. 5 is a cross-sectional view illustrating a state in which warpage occurs at the semiconductor package of FIG. 1. In FIG. 5, some components are omitted and/or several components are merged with each other so as to be illustrated as a single component, for the purpose of ease and convenience in explanation and illustration.

Referring to FIG. 5, a first semiconductor chip 100 and a second semiconductor chip 200 may be provided. Smile warpage may occur at the second semiconductor chip 200. A bottom surface of the second semiconductor chip 200 may not be flat. An outer portion of the second semiconductor chip 200 may be warped in the second direction D2. A level of a central portion of the bottom surface of the second semiconductor chip 200 may be lower than a level of an outer portion of the bottom surface of the second semiconductor chip 200. The second lower pads 230 may be disposed to be inclined along the bottom surface of the second semiconductor chip 200. A (separation) distance between a top surface of the first semiconductor chip 100 and the bottom surface of the second semiconductor chip 200 may increase from a central portion of the top surface of the first semiconductor chip 100 toward an outer portion of the top surface of the first semiconductor chip 100.

Arrangement of first and second regions A1 and A2 may be the same as described in FIG. 1. The first region A1 of the first semiconductor chip 100 may be a region on which the first pads 130 are provided, and the first pads 130 may be disposed on the outer portion of the top surface of the first semiconductor chip 100. The second region A2 of the first semiconductor chip 100 may be a region on which the second pads 140 are provided, and the second pads 140 may be disposed on the central portion of the top surface of the first semiconductor chip 100.

Since the smile warpage occurs, the (separation) distance between the top surface of the first semiconductor chip 100 and the bottom surface of the second semiconductor chip 200 may increase from the second region A2 toward the first region A1. A first (separation) distance P1 between the top surface of the first semiconductor chip 100 and the bottom surface of the second semiconductor chip 200 on the first region A1 may be greater than a second (separation) distance P2 between the top surface of the first semiconductor chip 100 and the bottom surface of the second semiconductor chip 200 on the second region A2. A lowermost level of the third pads 232 on the first region A1 may be higher than a lowermost level of the fourth pads 234 on the second region A2.

According to the disclosure, the first pads 130 may include the first protrusions 134 additionally provided on the first pad portions 132, and thus the third heights H3 of the first pads 130 on the first region A1 may be greater than the fourth heights H4 of the second pads 140 on the second region A2. As a result, even though the (separation) distance between the top surface of the first semiconductor chip 100 and the bottom surface of the second semiconductor chip 200 increases from the second region A2 toward the first region A1, a difference between a level of the top surface of the first pad 130 and a level of the bottom surface of the third pad 232 may be similar to a difference between a level of the top surface of the second pad 140 and a level of the bottom surface of the fourth pad 234. Even though the (separation) distance between the top surface of the first semiconductor chip 100 and the bottom surface of the second semiconductor chip 200 increases from the central portion of the first semiconductor chip 100 toward the outer portion of the first semiconductor chip 100 by the smile warpage, the first protrusions 134 of the first pads 130 may be electrically connected to the third pads 232 through the first connection terminals 252. In other words, the (separation) distance between the top surface of the first semiconductor chip 100 and the bottom surface of the second semiconductor chip 200 may increase on the outer portion of the first semiconductor chip 100 by the smile warpage, and the first protrusions 134 may compensate for the increase. Thus, the second semiconductor chip 200 may be electrically connected to the first semiconductor chip 100 through the first connection terminals 252 and the first pads 130. As a result, reliability of the semiconductor package may be improved.

In FIGS. 1 to 5, the first region A1 is described as the outer portion of the first semiconductor chip 100 which surrounds the second region A2 in a plan view, but embodiments of the disclosure are not limited thereto.

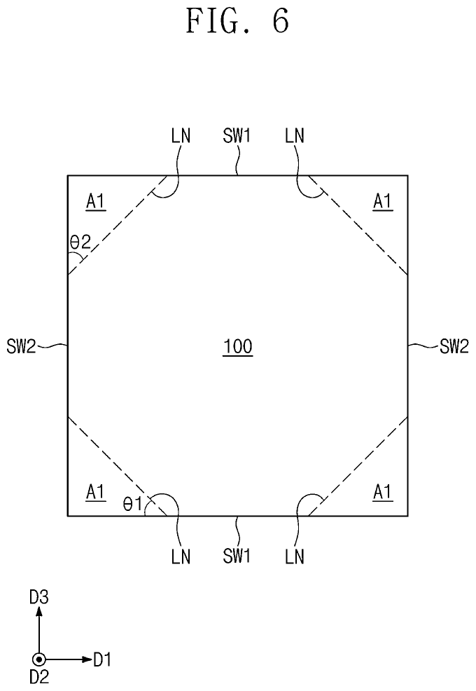

FIG. 6 is a plan view illustrating arrangement of a first region of a semiconductor package according to one or more embodiments of the disclosure.

Referring to FIG. 6, a first region A1 may be provided in plurality. The plurality of first regions A1 may include corner regions of the first semiconductor chip 100, respectively. The plurality of first regions A1 may be spaced apart from each other. A second region A2 may be a remaining region of the first semiconductor chip 100 except the plurality of first regions A1. The first semiconductor chip 100 may have first side surfaces SW1 parallel to the first direction D1 and second side surfaces SW2 parallel to the third direction D3. Each of corners of the first semiconductor chip 100 may be a portion at which the first and second side surfaces SW1 and SW2 adjacent to each other meet each other. In the disclosure, the corner region may be a triangular region including the corner when viewed in a plan view. Each of the corner regions may be defined by a line LN diagonally crossing the first side surface SW1 and the second side surface SW2 which are adjacent to each other. The line LN may not cross a center of the first side surface SW1 and may not cross a center of the second side surface SW2. For example, the line LN may cross a portion of the first side surface SW1 which is located between the center of the first side surface SW1 and the corner, and the line LN may cross a portion of the second side surface SW2 which is located between the center of the second side surface SW2 and the corner. A first angle θ1 between the line LN and the first side surface SW1 may be equal to or greater than about 20 degrees and less than about 90 degrees. A second angle θ2 between the line LN and the second side surface SW2 may be equal to or greater than about 20 degrees and less than about 90 degrees. In one or more embodiments, the first angle θ1 may be substantially equal to the second angle θ2.

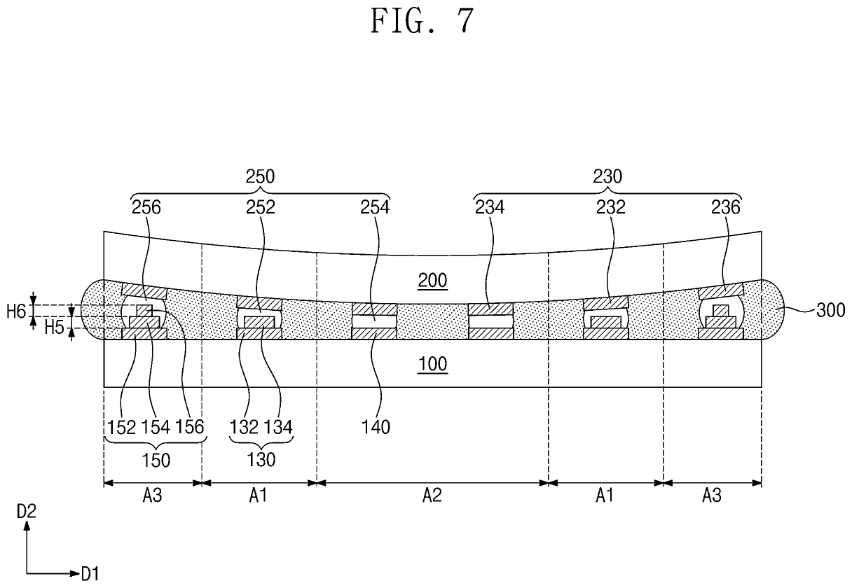

FIG. 7 is a cross-sectional view illustrating a state in which warpage occurs at a semiconductor package according to one or more embodiments of the disclosure. In FIG. 7, some components are omitted and/or several components are merged with each other so as to be illustrated as a single component, for the purpose of ease and convenience in explanation and illustration.

Referring to FIG. 7, a first semiconductor chip 100 and a second semiconductor chip 200 at which smile warpage occurs may be provided, like FIG. 5.

The first semiconductor chip 100 may further include a third region A3. A second region A2 may correspond to a central portion of the first semiconductor chip 100. A first region A1 may surround the second region A2 when viewed in a plan view. The third region A3 may surround the first region A1 when viewed in a plan view. The third region A3 may correspond to an outer portion of the first semiconductor chip 100. In other words, the first region A1 may be disposed between the second region A2 corresponding to the central portion of the first semiconductor chip 100 and the third region A3 corresponding to the outer portion of the first semiconductor chip 100. The third region A3 may be located at the outermost position of the first semiconductor chip 100.

The third region A3 may have a closed shape extending along an edge of the first semiconductor chip 100. A (separation) distance between a top surface of the first semiconductor chip 100 and a bottom surface of the second semiconductor chip 200 may increase from the central portion of the first semiconductor chip 100 toward the outer portion of the first semiconductor chip 100. In other words, the (separation) distance may increase from the second region A2 toward the first region A1 and from the first region A1 toward the third region A3.

In the third region A3, fifth pads 150 may be provided on the top surface of the first semiconductor chip 100. The fifth pads 150 may be arranged to surround the first region A1 when viewed in a plan view and may be spaced apart from each other. The fifth pads 150 may be disposed on the top surface of the first base layer 110. The fifth pads 150 may protrude from the top surface of the first semiconductor chip 100. Each of the fifth pads 150 may be connected to the top surface of each of the first through-electrodes 112 disposed in the first semiconductor chip 100 in the third region A3. Each of the fifth pads 150 may include a second pad portion 152, a second protrusion 154 protruding from a top surface of the second pad portion 152, and a third protrusion 156 protruding from a top surface of the second protrusion 154.

Each of the second pad portions 152 may have a circular shape or a polygonal shape when viewed in a plan view. For example, a planar shape of each of the second pad portions 152 may be an octagonal shape. Each of the second pad portions 152 may have the same shape as each of the first pad portions 132. However, embodiments of the disclosure are not limited thereto. A height of each of the second pad portions 152 in the second direction D2 may range from about 1 μm to about 5 μm. A width of each of the second pad portions 152 in the first direction D1 may be equal to or greater than the first width W1 of each of the first pad portions 132. The second pad portions 152 may include a conductive material. For example, the conductive material may include a metal such as nickel (Ni), copper (Cu), gold (Au), aluminum (Al) and/or tungsten (W).

Each of the second protrusions 154 may protrude from the top surface of a corresponding one of the second pad portions 152 in the second direction D2. A bottom surface of the second protrusion 154 may be in contact with the top surface of the second pad portion 152. The bottom surface of the second protrusion 154 may be located on the central portion of the top surface of the second pad portion 152. In other words, the second protrusion 154 may be spaced apart from both side surfaces of the second pad portion 152. The whole of the second protrusion 154 may vertically overlap with the second pad portion 152 corresponding to the second protrusion 154 when viewed in a plan view.

Each of the second protrusions 154 may have a circular shape or a polygonal shape when viewed in a plan view. For example, a planar shape of each of the second protrusions 154 may be an octagonal shape. The planar shape of the second protrusion 154 may be substantially the same as the planar shape of the second pad portion 152. However, embodiments of the disclosure are not limited thereto. A width of each of the second protrusions 154 in the first direction D1 may be less than the width of each of the second pad portions 152 in the first direction D1. The width of the second protrusion 154 in the first direction D1 may range from about 70% to about 90% of the width of the second pad portion 152 in the first direction D1. A fifth height H5 of each of the second protrusions 154 in the second direction D2 may range from about 1 μm to about 5 μm. The second protrusions 154 may include a conductive material. For example, the conductive material may include a metal such as nickel (Ni), copper (Cu), gold (Au), aluminum (Al) and/or tungsten (W).

Each of the third protrusions 156 may protrude from the top surface of a corresponding one of the second protrusions 154 in the second direction D2. A bottom surface of the third protrusion 156 may be in contact with the top surface of the second protrusion 154. The bottom surface of the third protrusion 156 may be located on a central portion of the top surface of the second protrusion 154. In other words, the third protrusion 156 may be spaced apart from both side surfaces of the second protrusion 154. The whole of the third protrusion 156 may vertically overlap with the second protrusion 154 corresponding to the third protrusion 156 when viewed in a plan view,

Each of the third protrusions 156 may have a circular shape, a polygonal shape, or a cross shape when viewed in a plan view. A width of each of the third protrusions 156 in the first direction D1 may be less than the width of each of the second protrusions 154 in the first direction D1. The width of the third protrusion 156 in the first direction D1 may range from about 50% to about 90% of the width of the second protrusion 154 in the first direction D1. A sixth height H6 of each of the third protrusions 156 in the second direction D2 may range from about 1 μm to about 5 μm. The third protrusions 156 may include a conductive material. For example, the conductive material may include a metal such as nickel (Ni), copper (Cu), gold (Au), aluminum (Al) and/or tungsten (W). The material of the third protrusions 156 may be the same as the material of the second protrusions 154.

The third protrusion 156 has a uniform width in FIG. 7, but embodiments of the disclosure are not limited thereto. In certain embodiments, the width of the third protrusion 156 in the first direction D1 may not be uniform. The width of the third protrusion 156 in the first direction D1 may become progressively less from the bottom surface toward a top surface of the third protrusion 156. For example, a cross section of the third protrusion 156 may have a triangular shape or a trapezoid shape. In this case, the width of the third protrusion 156 in the first direction D1 may mean a width in the first direction D1 at a contact area between the third protrusion 156 and the second protrusion 154.

In certain embodiments, the top surface of the third protrusion 156 may not be flat. The third protrusion 156 may include at least one concave portion in the top surface of the third protrusion 156. The concave portion may have a shape recessed from the top surface of the third protrusion 156 into the third protrusion 156. The concave portion may not completely penetrate the third protrusion 156. In other words, a depth of the concave portion in the second direction D2 may be less than the sixth height H6 of the third protrusion 156. A level of a bottom surface of the concave portion may be higher than a level of the bottom surface of the third protrusion 156. The concave portion may be provided in plurality. The plurality of concave portions may be spaced apart from each other in the top surface of each of the third protrusions 156. The concave portion may be omitted as needed.

Second lower pads 230 of the second semiconductor chip 200 may further include sixth pads 236 disposed on a top surface of the fifth pad 150 on the third region A3.

Each of the sixth pads 236 may face a corresponding one of the fifth pads 150. A bottom surface of the sixth pad 236 may face the top surface of the fifth pad 150. A width of each of the sixth pads 236 in the first direction D1 may be equal to the width of each of the second pad portions 152 in the first direction D1. However, embodiments of the disclosure are not limited thereto. In certain embodiments, the width of the sixth pad 236 in the first direction D1 may be equal to or greater than the width of the second protrusion 154 in the first direction D1. At least a portion of the sixth pad 236 may vertically overlap with the second pad portion 152 corresponding to the sixth pad 236 when viewed in a plan view. The sixth pad 236 may vertically overlap with the whole of the second protrusion 154.

Connection terminals 250 on a bottom surface of the second semiconductor chip 200 may further include third connection terminals 256 disposed on the bottom surfaces of the sixth pads 236. On the third region A3, each of the third connection terminals 256 may be disposed between a corresponding one of the fifth pads 150 and a corresponding one of the sixth pads 236, which face each other. One end of each of the third connection terminals 256 may be in contact with the bottom surface of the corresponding sixth pad 236. Another end of each of the third connection terminals 256 may be in contact with the top surface of the second pad portion 152 facing the corresponding sixth pad 236.

Each of the third connection terminals 256 may surround side surfaces of the second and third protrusions 154 and 156 of the corresponding fifth pad 150. The second and third protrusions 154 and 156 may be inserted in the third connection terminal 256. A bottom surface of the third connection terminal 256 may be in contact with the top surface of the second pad portion 152. The top surface and the side surface of the third protrusion 156 and the top surface and the side surface of the second protrusion 154 may be located in the third connection terminal 256.

A width of each of the third connection terminals 256 in the first direction D1 may be greater than the width of each of the sixth pads 236 in the first direction D1. The third connection terminal 256 may laterally protrude from a side surface of the sixth pad 236. However, embodiments of the disclosure are not limited thereto. In certain embodiments, the width of the third connection terminal 256 in the first direction D1 may be equal to or less than the width of the sixth pad 236 in the first direction D1.

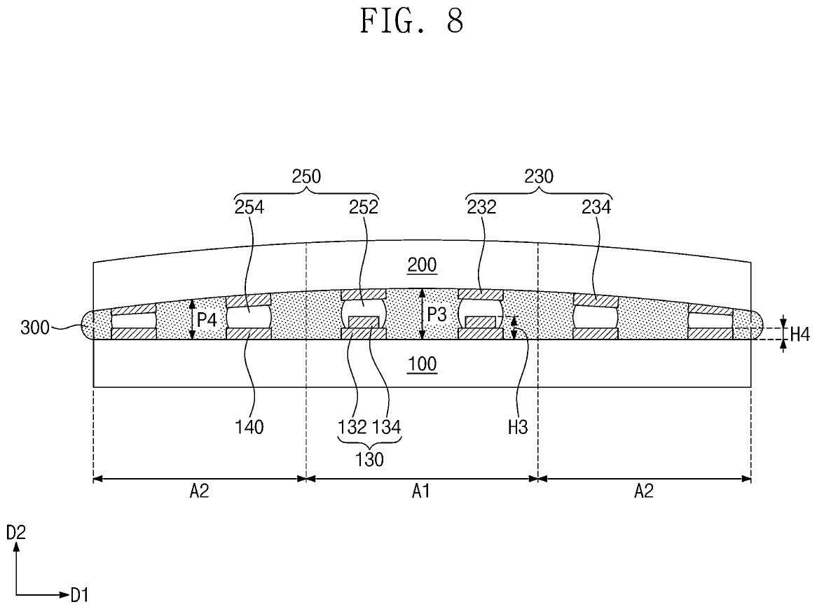

FIG. 8 is a cross-sectional view illustrating a state in which warpage occurs at a semiconductor package according to one or more embodiments of the disclosure. In FIG. 8, some components are omitted and/or several components are merged with each other so as to be illustrated as a single component, for the purpose of ease and convenience in explanation and illustration.

Referring to FIG. 8, a first semiconductor chip 100 and a second semiconductor chip 200 may be provided. Unlike FIGS. 5 and 7, cry warpage may occur at the second semiconductor chip 200. A bottom surface of the second semiconductor chip 200 may not be flat. An outer portion of the second semiconductor chip 200 may be warped in the opposite direction to the second direction D2. A level of a central portion of the bottom surface of the second semiconductor chip 200 may be higher than a level of an outer portion of the bottom surface of the second semiconductor chip 200. Second lower pads 230 may be disposed to be inclined along the bottom surface of the second semiconductor chip 200. A (separation) distance between a top surface of the first semiconductor chip 100 and the bottom surface of the second semiconductor chip 200 may decrease from a central portion of the top surface of the first semiconductor chip 100 toward an outer portion of the top surface of the first semiconductor chip 100.

The first region A1 corresponds to the outer portion of the first semiconductor chip 100 in FIGS. 1 to 7, but embodiments of the disclosure are not limited thereto. Unlike FIGS. 1 to 7, a first region A1 may correspond to the central portion of the first semiconductor chip 100. A second region A2 may correspond to the outer portion of the first semiconductor chip 100. The second region A2 may surround the first region A1 when viewed in a plan view. The second region A2 may have a closed shape extending along an edge of the first semiconductor chip 100. The first region A1 of the first semiconductor chip 100 may be a region on which first pads 130 are provided, and the first pads 130 may be disposed on the central portion of the top surface of the first semiconductor chip 100. The second region A2 of the first semiconductor chip 100 may be a region on which second pads 140 are provided, and the second pads 140 may be disposed on the outer portion of the top surface of the first semiconductor chip 100.

Since the cry warpage occurs, the (separation) distance between the top surface of the first semiconductor chip 100 and the bottom surface of the second semiconductor chip 200 may increase from the second region A2 toward the first region A1. A third (separation) distance P3 between the top surface of the first semiconductor chip 100 and the bottom surface of the second semiconductor chip 200 on the first region A1 may be greater than a fourth (separation) distance P4 between the top surface of the first semiconductor chip 100 and the bottom surface of the second semiconductor chip 200 on the second region A2. A lowermost level of third pads 232 on the first region A1 may be higher than a lowermost level of fourth pads 234 on the second region A2.

According to the disclosure, each of the first pads 130 may further include the first protrusion 134 additionally provided on the first pad portion 132, and thus the third height H3 of the first pad 130 of the first region A1 may be greater than the fourth height H4 of the second pad 140 of the second region A2. As a result, even though the (separation) distance between the top surface of the first semiconductor chip 100 and the bottom surface of the second semiconductor chip 200 increases from the second region A2 toward the first region A1, a difference between a level of the top surface of the first pad 130 and a level of the bottom surface of the third pad 232 may be similar to a difference between a level of the top surface of the second pad 140 and a level of the bottom surface of the fourth pad 234. Even though the (separation) distance between the top surface of the first semiconductor chip 100 and the bottom surface of the second semiconductor chip 200 increases from the outer portion of the first semiconductor chip 100 toward the central portion of the first semiconductor chip 100 by the cry warpage, the first protrusions 134 of the first pads 130 may be electrically connected to the third pads 232 through the first connection terminals 252. In other words, the (separation) distance between the top surface of the first semiconductor chip 100 and the bottom surface of the second semiconductor chip 200 may increase on the central portion of the first semiconductor chip 100 by the cry warpage, and the first protrusions 134 may compensate for the increase. Thus, the second semiconductor chip 200 may be electrically connected to the first semiconductor chip 100 through the first connection terminals 252, the first protrusions 134 and the first pads 130. As a result, reliability of the semiconductor package may be improved.

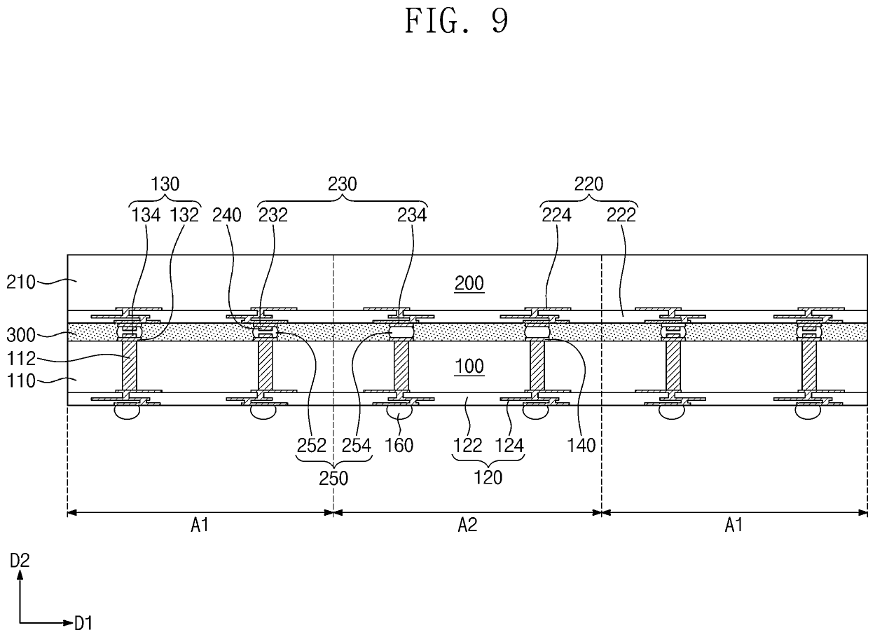

Referring to FIG. 9, a first semiconductor chip 100 and a second semiconductor chip 200 may be provided. Second lower pads 230 may include third and fourth pads 232 and 234. However, unlike the embodiments of FIG. 1, each of the third pads 232 may further include a fourth protrusion 240 protruding from a bottom surface of the third pad 232.

Each of the fourth protrusions 240 may protrude from the bottom surface of a corresponding one of the third pads 232 in the opposite direction to the second direction D2. A top surface of Each of the fourth protrusions 240 may be in contact with the bottom surface of the corresponding third pad 232. The top surface of the fourth protrusion 240 may be located on a central portion of the bottom surface of the third pad 232. In other words, the fourth protrusion 240 may be spaced apart from side surfaces of the third pad 232. The whole of the fourth protrusion 240 may overlap with the third pad 232 corresponding to the fourth protrusion 240 when viewed in a plan view. The fourth protrusions 240 may be electrically connected to the second semiconductor chip 200 through the third pads 232.

Each of the fourth protrusions 240 may have a circular shape, a polygonal shape, or a cross shape when viewed in a plan view. A width of each of the fourth protrusions 240 in the first direction D1 may be less than a width of each of the third pads 232 in the first direction D1. The width of the fourth protrusion 240 in the first direction D1 may range from about 70% to about 90% of the width of the third pad 232 in the first direction D1. A height of each of the fourth protrusions 240 in the second direction D2 may range from about 1 μm to about 5 μm. The fourth protrusions 240 may include a conductive material. For example, the conductive material may include a metal such as nickel (Ni), copper (Cu), gold (Au), aluminum (Al) and/or tungsten (W). The material of the fourth protrusions 240 may be different from the material of the third pads 232.

The fourth protrusion 240 and the third pad 232 are formed of different materials and an interface exists between the fourth protrusion 240 and the third pad 232 in FIG. 9, but embodiments of the disclosure are not limited thereto. In certain embodiments, the material of the fourth protrusions 240 may be the same as the material of the third pads 232. In this case, each of the fourth protrusions 240 and the third pad 232 corresponding thereto may be formed in a single body. In other words, the fourth protrusion 240 and the third pad 232 may constitute a continuous component, and the interface between the third pad 232 and the fourth protrusion 240 may not be visible.

Each of the fourth protrusions 240 has a uniform width in FIG. 9, but embodiments of the disclosure are not limited thereto. The width of the fourth protrusion 240 in the first direction D1 may not be uniform. For example, the width of the fourth protrusion 240 may become progressively less from the top surface toward a bottom surface of the fourth protrusion 240. A cross section of each of the fourth protrusions 240 may have a triangular shape or a trapezoid shape. In this case, the width of the fourth protrusion 240 in the first direction D1 may mean a width in the first direction D1 at a contact area between the fourth protrusion 240 and the third pad 232.

In addition, even though not shown in the drawings, the bottom surface of the fourth protrusion 240 may not be flat. The fourth protrusion 240 may include at least one concave portion in the bottom surface of the fourth protrusion 240. The concave portion may have a shape recessed from the bottom surface of the fourth protrusion 240 into the fourth protrusion 240. A level of a top surface of the concave portion may be higher than a level of the bottom surface of the fourth protrusion 240. The concave portion may be provided in plurality. The plurality of concave portions may be spaced apart from each other in the bottom surface of each of the fourth protrusions 240. The concave portion may be omitted as needed.

First connection terminals 252 may be disposed on the bottom surfaces of the third pads 232. Second connection terminals 254 may be disposed on bottom surfaces of the fourth pads 234. The fourth pads 234, the first connection terminals 252 and the second connection terminals 254 may be the same or similar as described with reference to FIG. 1.

Since the third pads 232 further include the fourth protrusions 240 protruding from the bottom surfaces of the third pads 232, the first connection terminals 252 may surround the bottom surfaces and side surfaces of the fourth protrusions 240. The fourth protrusions 240 may be inserted in the first connection terminals 252. The bottom surfaces and the side surfaces of the fourth protrusions 240 may be located in the first connection terminals 252.

Since the third pads 232 have the fourth protrusions 240 protruding from the bottom surfaces of the third pads 232, a (separation) distance between the first semiconductor chip 100 and the second semiconductor chip 200 may be shortened on the first region A1. In other words, even though the (separation) distance between the first semiconductor chip 100 and the second semiconductor chip 200 increases from the second region A2 toward the first region A1 by warpage occurring at the semiconductor package, the first connection terminals 252 may be stably connected to the fourth protrusions 240 and the first protrusions 134. Thus, the semiconductor package with improved electrical stability may be provided.

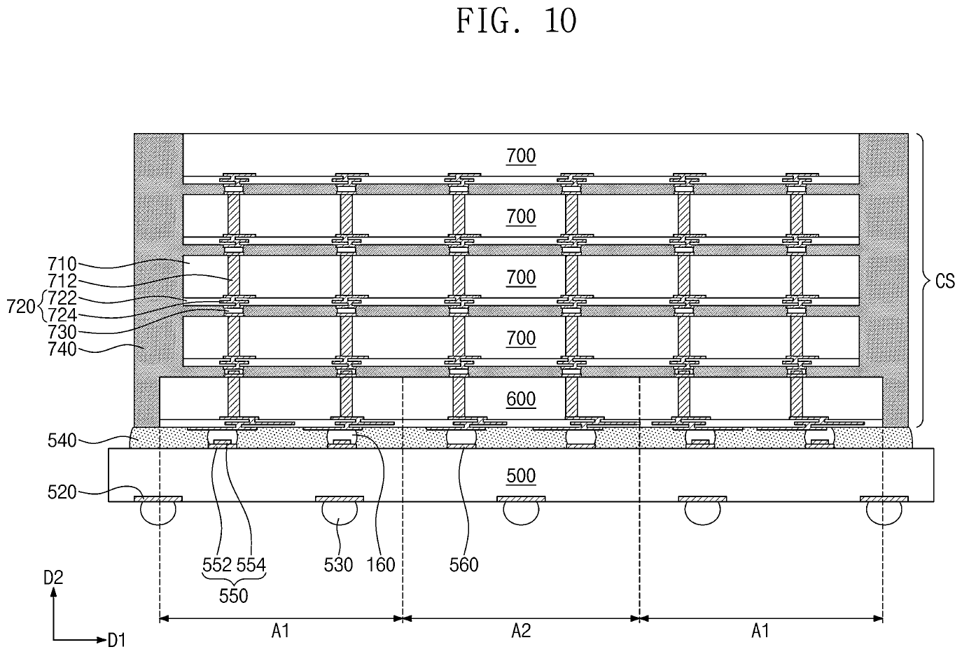

FIG. 10 is a cross-sectional view illustrating a semiconductor package according to one or more embodiments of the disclosure.

Referring to FIG. 10, a chip stack CS may be provided. The chip stack CS may include a base chip 600, third semiconductor chips 700 stacked on the base chip 600, and a molding layer 740 surrounding the third semiconductor chips 700. Hereinafter, the components of the chip stack CS will be described in detail.

The base chip 600 may be substantially the same or similar as the first semiconductor chip 100 (see FIG. 1) described with reference to FIG. 1. The third semiconductor chip 700 may be provided on the base chip 600. A bottom surface of the third semiconductor chip 700 may be an active surface. A width of the third semiconductor chip 700 may be less than a width of the base chip 600. The third semiconductor chip 700 may include a third base layer 710, a third interconnection layer 720, and second through-electrodes 712.

The third base layer 710 may be a semiconductor substrate. For example, the third base layer 710 may include silicon (Si). The third base layer 710 may be a silicon (Si) substrate, a silicon-on-insulator (SOI) substrate, a germanium (Ge) substrate, a germanium-on-insulator (GOI) substrate, a silicon-germanium (SiGe) substrate, a group III-V semiconductor substrate, or a substrate having an epitaxial thin layer obtained by performing a selective epitaxial growth (SEG) process. For example, the third base layer 710 may include at least one of silicon (Si), germanium (Ge), silicon-germanium (SiGe), gallium arsenic (GaAs), indium gallium arsenic (InGaAs), aluminum gallium arsenic (AlGaAs), or any mixture thereof. In an embodiment, an integrated circuit may be provided on a bottom surface of the third base layer 710. The integrated circuit may include a logic circuit or a memory circuit. In other words, the third semiconductor chip 700 may be a logic chip or a memory chip. However, embodiments of the disclosure are not limited thereto, and in certain embodiments, the third semiconductor chip 700 may include the logic chip, the memory chip, a semiconductor chip including at least one of other various integrated devices, or a passive device.

The third interconnection layer 720 may be disposed on the bottom surface of the third base layer 710. For example, the third interconnection layer 720 may include a third insulating pattern 722 and a third interconnection pattern 724 which are formed on the bottom surface of the third base layer 710. The third interconnection layer 720 may further include a circuit pattern or a protective layer as needed.

The third insulating pattern 722 may be disposed on the bottom surface of the third base layer 710 to cover the integrated circuit. The third insulating pattern 722 may include an insulating material. For example, the third insulating pattern 722 may include silicon oxide (SiO), silicon nitride (SiN), silicon oxynitride (SiON), silicon carbonitride (SiCN), or an insulating polymer. Alternatively, the third insulating pattern 722 may include an insulating polymer or a photoimageable dielectric material (PID). For example, the photoimageable dielectric material may include at least one of photosensitive polyimide, polybenzoxazole, a phenol-based polymer, or a benzocyclobutene-based polymer.

The third interconnection pattern 724 may be provided in the third insulating pattern 722. The third interconnection pattern 724 may be electrically connected to the integrated circuit formed on the bottom surface of the third base layer 710. The third interconnection pattern 724 may include a conductive material. For example, the third interconnection pattern 724 may include copper (Cu) or aluminum (Al).

The third semiconductor chip 700 may include third lower pads provided on a bottom surface of the third semiconductor chip 700. The third lower pads may be disposed on the bottom surface of the third semiconductor chip 700 (i.e., a bottom surface of the third interconnection layer 720). In other words, the third lower pads may be exposed on the bottom surface of the third semiconductor chip 700. Here, the third lower pads may be portions of the third interconnection pattern 724 which are exposed at a bottom surface of the third insulating pattern 722 of the third interconnection layer 720 or may be additional pads disposed on the bottom surface of the third insulating pattern 722 of the third interconnection layer 720 so as to be connected to the third interconnection pattern 724. The third lower pads may be electrically connected to the integrated circuit, formed on the bottom surface of the third base layer 710, through the third interconnection pattern 724 in the third interconnection layer 720.

Connection bumps 730 may be provided on the bottom surface of the third semiconductor chip 700. The connection bumps 730 may be provided on bottom surfaces of the third lower pads. Each of the connection bumps 730 may include a solder ball or a solder bump. The connection bumps 730 may be electrically connected to the integrated circuit of the third semiconductor chip 700 through the third lower pads.

The second through-electrodes 712 may be provided in the third semiconductor chip 700. The second through-electrodes 712 may vertically penetrate the third base layer 710. One end of each of the second through-electrodes 712 may be connected to the third interconnection layer 720. The one end of the second through-electrode 712 may be electrically connected to the third interconnection pattern 724 of the third interconnection layer 720 or the integrated circuit formed on the bottom surface of the third base layer 710. Another end of each of the second through-electrodes 712 may be exposed at a top surface of the third base layer 710. At least one of the second through-electrodes 712 may be provided on each of the first region A1 and the second region A2.

The third semiconductor chip 700 may be provided as a plurality of third semiconductor chips 700. For example, the plurality of third semiconductor chips 700 may be stacked on the base chip 600. The number of the stacked third semiconductor chips 700 may range from 8 to 32. The connection bumps 730 may be provided between the third semiconductor chips 700 adjacent to each other. Here, an uppermost one of the third semiconductor chips 700 may not include the second through-electrodes 712. In addition, a thickness of the uppermost third semiconductor chip 700 may be greater than thicknesses of other third semiconductor chips 700 disposed thereunder.

Adhesive layers may be provided between the third semiconductor chips 700. Each of the adhesive layers may include a non-conductive film (NCF). The adhesive layers may surround the connection bumps 730 between the third semiconductor chips 700 and may prevent occurrence of electrical short between the connection bumps 730.

The molding layer 740 may be disposed on a top surface of the base chip 600. The molding layer 740 may cover the top surface of the base chip 600. The molding layer 740 may surround the third semiconductor chips 700. A top surface of the molding layer 740 may be coplanar with a top surface of the uppermost third semiconductor chip 700. The uppermost third semiconductor chip 700 may be exposed from the top surface of the molding layer 740. The molding layer 740 may include an insulating polymer material. For example, the molding layer 740 may include an epoxy molding compound (EMC).

A substrate 500 may be provided on a bottom surface of the chip stack CS. The substrate 500 may include a printed circuit board (PCB) or a semiconductor substrate. The substrate 500 may have upper substrate pads and an internal interconnection pattern. The upper substrate pads may be disposed on a top surface of the substrate 500. The upper substrate pads may protrude from the top surface of the substrate 500. The upper substrate pads may include seventh pads 550 disposed on the top surface of the substrate 500 of the first region A1, and eighth pads 560 disposed on the top surface of the substrate 500 of the second region A2. The internal interconnection pattern may be provided in the substrate 500 and may be electrically connected to the upper substrate pads.

The substrate 500 is the printed circuit board in FIG. 10, but embodiments of the disclosure are not limited thereto. In certain embodiments, the substrate 500 may be a redistribution substrate. For example, the substrate 500 may include a single substrate interconnection layer or at least two or more stacked substrate interconnection layers. In the disclosure, the substrate interconnection layer may mean an interconnection layer formed by patterning an insulating material layer and patterning a conductive material layer. Each of the substrate interconnection layers may include an insulating pattern and a conductive pattern in the insulating pattern. The conductive pattern of one substrate interconnection layer may be electrically connected to the conductive pattern of another substrate interconnection layer adjacent to the one substrate interconnection layer. Upper portions of the conductive patterns of an uppermost one of the substrate interconnection layers may correspond to the upper substrate pads. Hereinafter, the embodiments of FIG. 10 will be described continuously.

Lower substrate pads 520 may be provided at a bottom surface of the substrate 500. The lower substrate pads 520 may be electrically connected to the internal interconnection pattern of the substrate 500. The lower substrate pads 520 may include a conductive material such as a metal. For example, the lower substrate pads 520 may include copper (Cu).

Substrate connection terminals 530 may be provided on bottom surfaces of the lower substrate pads 520. More particularly, each of the substrate connection terminals 530 may be connected to the bottom surface of a corresponding one of the lower substrate pads 520. Each of the substrate connection terminals 530 may include a solder ball or a solder bump. The substrate connection terminals 530 may include an alloy including at least one of tin (Sn), silver (Ag), copper (Cu), nickel (Ni), bismuth (Bi), indium (In), antimony (Sb), or cerium (Ce). Depending on a kind and arrangement of the substrate connection terminals 530, the semiconductor package may be provided in the form of a ball grid array (BGA), a fine ball grid array (FBGA) or a land grid array (LGA).

The seventh pads 550 may be provided on the top surface of the substrate 500 of the first region A1. The seventh pads 550 may be disposed on an outer portion of the substrate 500. The seventh pads 550 may protrude from the top surface of the substrate 500. Each of the seventh pads 550 may be disposed on a bottom surface of a corresponding one of the external terminals 160 on the first region A1. The seventh pads 550 may be arranged to surround the second region A2 when viewed in a plan view and may be spaced apart from each other. Each of the seventh pads 550 may include a third pad portion 552 and a fifth protrusion 554 protruding from a top surface of the third pad portion 552.

Each of the third pad portions 552 may have a circular shape or a polygonal shape when viewed in a plan view. For example, a planar shape of each of the third pad portions 552 may be an octagonal shape. However, embodiments of the disclosure are not limited thereto. The planar shape of the third pad portion 552 may be variously changed as needed. The third pad portions 552 may include a conductive material. For example, the conductive material may include a metal such as nickel (Ni), copper (Cu), gold (Au), aluminum (Al) and/or tungsten (W).

Each of the fifth protrusions 554 may protrude from the top surface of a corresponding one of the third pad portions 552 in the second direction D2. A bottom surface of each of the fifth protrusions 554 may be in contact with the top surface of each of the third pad portions 552. The bottom surface of the fifth protrusion 554 may be located on a central portion of the top surface of the third pad portion 552. In other words, the fifth protrusion 554 may be spaced apart from side surfaces of the third pad portion 552. The whole of the fifth protrusion 554 may vertically overlap with the third pad portion 552 corresponding to the fifth protrusion 554 when viewed in a plan view.

Each of the fifth protrusions 554 may have a circular shape or a polygonal shape when viewed in a plan view. For example, a planar shape of each of the fifth protrusions 554 may be an octagonal shape. The planar shape of the fifth protrusion 554 may be substantially the same as the planar shape of the third pad portion 552. However, embodiments of the disclosure are not limited thereto. A width of each of the fifth protrusions 554 in the first direction D1 may be less than a width of each of the third pad portions 552 in the first direction D1. The width of the fifth protrusion 554 in the first direction D1 may range from about 70% to about 90% of the width of the third pad portion 552 in the first direction D1. The fifth protrusions 554 may include a conductive material. For example, the conductive material may include a metal such as nickel (Ni), copper (Cu), gold (Au), aluminum (Al) and/or tungsten (W).

The eighth pads 560 may be disposed on the top surface of the substrate 500 of the second region A2. The eighth pads 560 may be spaced apart from each other on the top surface of the substrate 500 on the second region A2. The eighth pads 560 may be disposed on a central portion of the substrate 500. Each of the eighth pads 560 may be disposed on a bottom surface of each of the external terminals 160 disposed on a bottom surface of the base chip 600 of the second region A2. The eighth pads 560 may be horizontally spaced apart from the seventh pads 550. The seventh pads 550 may be arranged to surround the eighth pads 560 when viewed in a plan view, and the eighth pads 560 may be located between the seventh pads 550.

Each of the eighth pads 560 may have a circular shape or a polygonal shape when viewed in a plan view. For example, a planar shape of each of the eighth pads 560 may be an octagonal shape. The eighth pads 560 may have the same planar shape as the third pad portions 552. However, embodiments of the disclosure are not limited thereto, and in certain embodiments, the planar shape of the eighth pad 560 may be variously changed as needed. Each of the eighth pads 560 may have a flat top surface. A height of each of the eighth pads 560 in the second direction D2 may be equal to a height of each of the third pad portions 552 in the second direction D2. A width of each of the eighth pads 560 in the first direction D1 may be equal to or less than the width of each of the third pad portions 552 in the first direction D1. The eighth pads 560 may include a conductive material. For example, the conductive material may include a metal such as nickel (Ni), copper (Cu), gold (Au), aluminum (Al) and/or tungsten (W). The material of the eighth pads 560 may be the same as the material of the third pad portions 552.

The chip stack CS may be mounted on the substrate 500. For example, the chip stack CS may be connected to the upper substrate pads disposed on the top surface of the substrate 500 through the external terminals 160 of the base chip 600. A bottom surface of each of the external terminals 160 may be in contact with a top surface of a corresponding one of the upper substrate pads, and thus the chip stack CS and the substrate 500 may be electrically connected to each other.

An underfill layer 540 may be provided between the substrate 500 and the chip stack CS. The underfill layer 540 may fill an area between the base chip 600 and the substrate 500 and may surround the upper substrate pads and the external terminals 160.

Warpage may occur at a semiconductor package according to the disclosure. For example, Smile warpage may occur at the base chip 600. The bottom surface of the base chip 600 may not be flat. An outer portion of the base chip 600 may be warped in the second direction D2. A level of a central portion of the bottom surface of the base chip 600 may be lower than a level of an outer portion of the bottom surface of the base chip 600. A (separation) distance between the top surface of the substrate 500 and the bottom surface of the base chip 600 may increase from a central portion of the top surface of the substrate 500 toward an outer portion of the top surface of the substrate 500. Since the smile warpage occurs, the (separation) distance between the top surface of the substrate 500 and the bottom surface of the base chip 600 may increase from the second region A2 toward the first region A1.

According to the disclosure, the seventh pads 550 may include the fifth protrusions 554 additionally provided on the third pad portions 552, and thus a heights of the seventh pads 550 on the first region A1 may be greater than a heights of the eighth pads 560 on the second region A2. As a result, even though the (separation) distance between the top surface of the top surface of the substrate 500 and the bottom surface of the base chip 600 increases from the second region A2 toward the first region A1, the fifth protrusions 554 of the seventh pads 550 may be electrically connected to the bottom surface of the base chip 600. In other words, the (separation) distance between the top surface of the substrate 500 and the bottom surface of the base chip 600 may increase on the outer portion of the substrate 500 by the smile warpage, and the fifth protrusions 554 may compensate for the increase.

Smile warpage occurred at the base chip 600 in FIG. 10, but embodiments of the inventive disclosure are not limited thereto. In certain embodiments, cry warpage may occur at the base chip 600. Unlike FIG. 5, the first region A1 may correspond to the central portion of the base chip 600. The second region A2 may correspond to the outer portion of the base chip 600. The second region A2 may surround the first region A1 when viewed in a plan view. The second region A2 may have a closed shape extending along an edge of the base chip 600. The first region A1 of the base chip 600 may be a region on which seventh pads 550 are provided, and the seventh pads 550 may be disposed on the central portion of the top surface of the base chip 600. The second region A2 of the base chip 600 may be a region on which the eighth pads 560 are provided, and the eighth pads 560 may be disposed on the outer portion of the top surface of the base chip 600.

FIGS. 11 to 13 are cross-sectional views illustrating a method of manufacturing a semiconductor package according to one or more embodiments of the disclosure.

Referring to FIG. 11, a first semiconductor chip 100 may be formed. The first semiconductor chip 100 may be substantially the same as the first semiconductor chip 100 described with reference to FIG. 1. First through-electrodes 112 may be formed in the first semiconductor chip 100. The first through-electrodes 112 may be formed by filling trenches with a conductive material. The conductive material may include copper (Cu). A top surface of the first semiconductor chip 100 may be ground to expose the first through-electrodes 112. The top surface of the ground first semiconductor chip 100 may be planarized by a chemical mechanical polishing (CMP) process.

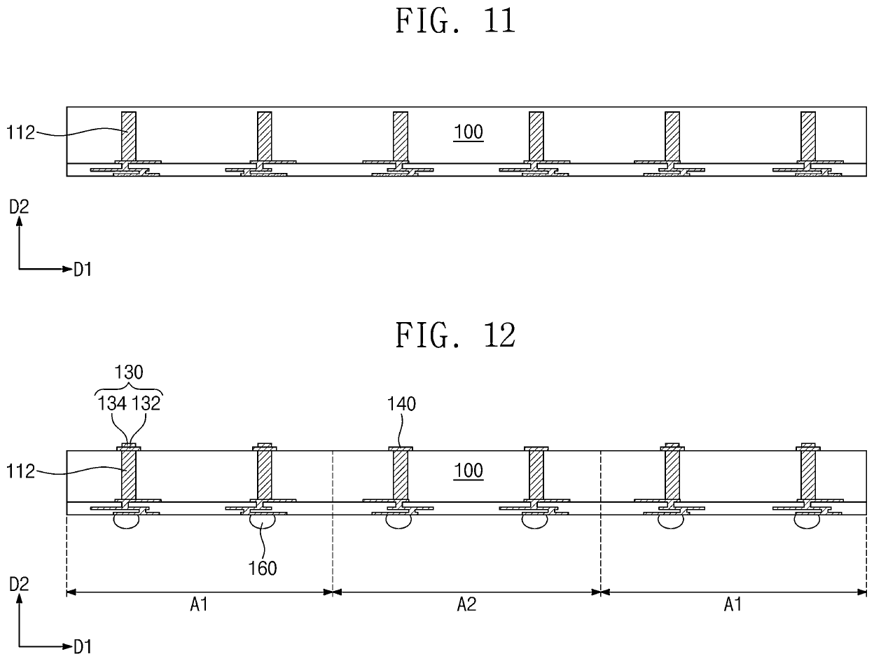

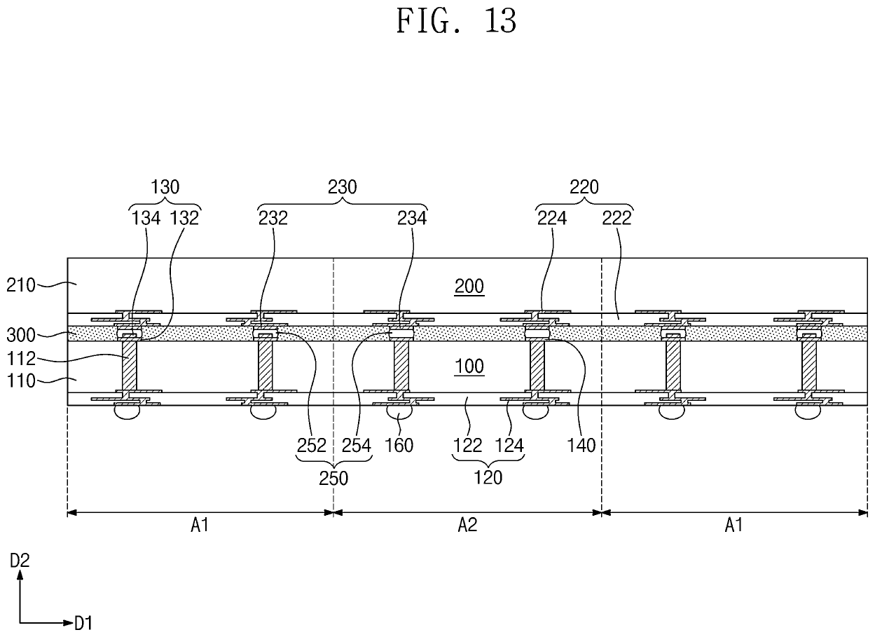

Referring to FIG. 12, first pad portions 132 and second pads 140 may be formed on the first through-electrodes 112 exposed at the top surface of the first semiconductor chip 100. The first pad portions 132 may be formed on a first region A1 corresponding to an outer portion of the first semiconductor chip 100. The second pads 140 may be formed on a second region A2 corresponding to a central portion of the first semiconductor chip 100. The first pad portions 132 and the second pads 140 may include a conductive material such as copper (Cu). The first pad portions 132 and the second pads 140 may be formed at the same time. Thereafter, first protrusions 134 may be formed on top surfaces of the first pad portions 132. A width of each of the first protrusions 134 in the first direction D1 may be less than a width of each of the first pad portions 132 in the first direction D1. The first pad portions 132 may include a conductive material such as copper (Cu). The first and second pads 130 and 140 may be electrically connected to the first through-electrodes 112 and an integrated circuit of the first semiconductor chip 100.

External terminals 160 may be disposed on a bottom surface of the first semiconductor chip 100. The external terminals 160 may be provided on bottom surfaces of first lower pads exposed at the bottom surface of the first semiconductor chip 100. For example, the external terminals 160 (e.g., solder balls or solder bumps) may be adhered or attached on the bottom surfaces of the first lower pads.

Referring to FIG. 13, a second semiconductor chip 200 may be mounted on the first semiconductor chip 100. Connection terminals 250 may be provided on a bottom surface of the second semiconductor chip 200. The connection terminals 250 may be provided on bottom surfaces of second lower pads 230 exposed on the bottom surface of the second semiconductor chip 200. For example, the connection terminals 250 (e.g., solder balls or solder bumps) may be adhered or attached on the bottom surfaces of the second lower pads 230.

An adhesive layer 300 surrounding the connection terminals 250 may be provided between the first semiconductor chip 100 and the second semiconductor chip 200. The adhesive layer 300 may be a non-conductive film (NCF) or non-conductive paste (NCP).

The first and second pads 130 and 140 of the first semiconductor chip 100 may be connected to the connection terminals 250 of the second semiconductor chip 200, and thus the second semiconductor chip 200 may be mounted on the top surface of the first semiconductor chip 100. The connection terminals 250 on the bottom surface of the second semiconductor chip 200 may be disposed to be located on the first and second pads 130 and 140 of the first semiconductor chip 100. Thereafter, the first and second pads 130 and 140 of the first semiconductor chip 100 may be bonded to the connection terminals 250 of the second semiconductor chip 200 by a thermal compression process or a reflow process.

Since the first pads 130 include the first protrusions 134 disposed on the top surfaces of the first pad portions 132, it is possible to minimize or prevent traps of the adhesive layer 300 (e.g., the NCF) between the first protrusions 134 and the first connection terminals 252. Areas of contact surfaces between the first pads 130 and the connection terminals 250 may be increased by the first protrusions 134, thereby preventing a trap phenomenon of the adhesive layer, which may occur in the bonding process. The semiconductor package of FIG. 1 may be manufactured as described above.

The semiconductor package according to one or more embodiments of the disclosure may include the pad having the protrusion, and thus it is possible to prevent failure in which pads between a chip and a substrate are not electrically connected to each other.

In addition, the semiconductor package according to one or more embodiments of the disclosure may include the pad having the protrusion, and thus the connection terminal may be in contact with the pad even though the warpage of the semiconductor chip occurs, thereby providing the semiconductor package with improved reliability.

While certain example embodiments of the disclosure have been particularly shown and described, it will be understood by one of ordinary skill in the art that variations in form and detail may be made therein without departing from the spirit and scope of the attached claims.

What is claimed is:

1. A semiconductor package comprising:
a first semiconductor chip having a first region and a second region contacting the first region;
a second semiconductor chip on a top surface of the first semiconductor chip;
a first connection terminal; and
a second connection terminal,
wherein the first semiconductor chip comprises:
a first pad in the first region and on the top surface of the first semiconductor chip, the first pad comprising a first pad portion and a first protrusion protruding from a top surface of the first pad portion; and
a second pad in the second region and on the top surface of the first semiconductor chip, the second pad having a flat top surface,
wherein the second semiconductor chip comprises:
a third pad in the first region and on a bottom surface of the second semiconductor chip; and
a fourth pad in the second region and on the bottom surface of the second semiconductor chip,
wherein the first pad and the third pad are connected to each other through the first connection terminal, and
wherein the second pad and the fourth pad are connected to each other through the second connection terminal.

2. The semiconductor package of claim 1, wherein the first region corresponds to an outer portion of the first semiconductor chip,
wherein the second region corresponds to a central portion of the first semiconductor chip,
wherein the first region surrounds the second region when viewed in a plan view, and
wherein a distance between the top surface of the first semiconductor chip and the bottom surface of the second semiconductor chip increases from the central portion of the first semiconductor chip toward the outer portion of the first semiconductor chip.

3. The semiconductor package of claim 2, wherein the first semiconductor chip further has a third region surrounding the first region when viewed in a plan view, and
wherein the first semiconductor chip further comprises a fifth pad in the third region and on the top surface of the first semiconductor chip,
wherein the fifth pad comprises:
a second pad portion;
a second protrusion protruding from a top surface of the second pad portion; and
a third protrusion protruding from a top surface of the second protrusion.

4. The semiconductor package of claim 1, wherein the first region corresponds to a central portion of the first semiconductor chip,
wherein the second region corresponds to an outer portion of the first semiconductor chip,
wherein the second region surrounds the first region when viewed in a plan view, and
wherein a distance between the top surface of the first semiconductor chip and the bottom surface of the second semiconductor chip decreases from the central portion of the first semiconductor chip toward the outer portion of the first semiconductor chip.

5. The semiconductor package of claim 1, wherein a width of the first protrusion ranges from about 70% to about 90% of a width of the first pad portion.

6. The semiconductor package of claim 1, wherein each of the first connection terminal and the second connection terminal comprises a solder ball or a solder bump, and
wherein the first connection terminal surrounds at least a portion of a side surface of the first protrusion.

7. The semiconductor package of claim 6, wherein a width of the first pad portion is greater than a width of the second pad, and
wherein a width of the first connection terminal is greater than a width of the second connection terminal.

8. The semiconductor package of claim 1, wherein the third pad further comprises a fourth protrusion protruding from a bottom surface of the third pad.

9. The semiconductor package of claim 1, wherein a planar shape of the first protrusion is a circular shape, a polygonal shape, or a cross shape.

10. The semiconductor package of claim 1, wherein a top surface of the first protrusion comprises at least one concave portion.

11. The semiconductor package of claim 1, wherein a height from a bottom surface of the first pad portion to a top surface of the first protrusion ranges from about 150% to about 250% of a height from a bottom surface of the second pad to the top surface of the second pad.

12. A semiconductor package comprising:
a substrate having a first region and a second region;
a base chip on the substrate;
second semiconductor chips stacked on a top surface of the base chip;
a substrate connection terminal on a bottom surface of the substrate; and
a molding layer surrounding the base chip and the second semiconductor chips on the substrate,
wherein the substrate comprises:
a first pad disposed on a top surface of the substrate of the first region;
a protrusion disposed on a top surface of the first pad; and
a second pad disposed on the top surface of the substrate of the second region,
wherein a width of the protrusion is less than a width of the first pad,
wherein the base chip is electrically connected to the substrate through a connection terminal provided on a bottom surface of the base chip, and
wherein a distance between the top surface of the substrate and the bottom surface of the base chip on the first region is greater than a distance between the top surface of the substrate and the bottom surface of the base chip on the second region.

13. The semiconductor package of claim 12, wherein the substrate includes:
a first side surface parallel to a first direction; and
a second side surface parallel to a second direction intersecting the first direction,
wherein the first region includes a corner region of the substrate, in which the first side surface and the second side surface meet each other.

14. The semiconductor package of claim 12, wherein a height from a bottom surface of the protrusion to a top surface of the protrusion ranges from about 50% to about 150% of a height from a bottom surface of the second pad to a top surface of the second pad.

15. The semiconductor package of claim 14, wherein
the first pad and the protrusion are formed of the same metal material and constitute a single body,
wherein the protrusion has at least one concave portion in a top surface of the protrusion, and
wherein the at least one concave portion has a shape recessed from the top surface of the protrusion into the protrusion.

16. The semiconductor package of claim 12, wherein the width of the protrusion becomes progressively less from a bottom surface of the protrusion toward a top surface of the protrusion

17. A semiconductor package comprising:
a first semiconductor chip having a central region and a peripheral region surrounding the central region in a plan view; and
a second semiconductor chip on a top surface of the first semiconductor chip,
wherein the first semiconductor chip comprises a first pad on the top surface of the first semiconductor chip and a second pad on the top surface of the first semiconductor chip,
wherein the first pad comprises at least one protrusion on a top surface of the first pad,
wherein a height of the first pad is greater than a height of the second pad,
wherein one of the first pad and the second pad is in the central region and on the top surface of the first semiconductor chip, and
wherein the other one of the first pad and the second pad is in the peripheral region and on the top surface of the first semiconductor chip.

18. The semiconductor package of claim 17, wherein a distance from the top surface of the first semiconductor chip to a bottom surface of the second semiconductor chip increases from the central region toward the peripheral region, and
wherein the second pad is in the central region, and the first pad is in the peripheral region.

19. The semiconductor package of claim 17, wherein a distance from the top surface of the first semiconductor chip to a bottom surface of the second semiconductor chip decreases from the central region toward the peripheral region, and
wherein the first pad is in the central region, and the second pad is in the peripheral region.

20. The semiconductor package of claim 17, wherein a planar shape of the at least one protrusion is a circular shape, a polygonal shape, or a cross shape.
